(19) United States
(12) Patent Application Publication
(10) Pub. No.: US 2025/0210439 A1
(43) Pub. Date: Jun. 26, 2025

(54) SEMICONDUCTOR DEVICE

(71) Applicant: Renesas Electronics Corporation, Tokyo (JP)

(72) Inventors: Yoshinori HOSHINO, Tokyo (JP); Hiroya SHIMOYAMA, Tokyo (JP); Toshimune KANBARA, Tokyo (JP); Masataka NOMURA, Tokyo (JP)

(21) Appl. No.: 18/931,234

(22) Filed: Oct. 30, 2024

(30) Foreign Application Priority Data
Dec. 22, 2023 (JP) 2023-216980

(51) Int. Cl. H01L 23/34; G01K 7/01; H01L 29/40; H01L 29/66; H01L 29/78

(52) U.S. Cl. CPC H01L 23/34; G01K 7/015; H10D 30/0297; H10D 30/668; H10D 64/117

(57) ABSTRACT

On a lower layer side of a temperature sensing diode, trenches are periodically formed in a semiconductor substrate. A source field plate is arranged in the trenches via an insulating film. A P type diffusion layer is formed between adjacent trenches. The source field plate and the P type diffusion layer are connected to a source potential.

### CROSS-REFERENCE TO RELATED APPLICATIONS

The disclosure of Japanese Patent Application No. 2023-216980 filed on Dec. 22, 2023 including the specification, drawings and abstract is incorporated herein by reference in its entirety.

### BACKGROUND

The present disclosure relates to a semiconductor device, and particularly relates to a semiconductor device including, for example, a diode for temperature measurement.

There are disclosed techniques listed below.
[Patent Document 1] Japanese Unexamined Patent Application Publication No. 2017-103272

Patent Document 1 describes a semiconductor device according to a related art, having a semiconductor substrate and a polysilicon diode (hereinafter also referred to as a temperature sensing diode) for detecting the temperature of the semiconductor substrate. The semiconductor substrate has a cell region in a center portion of a chip where an insulated gate type power transistor such as a power metal-oxide-semiconductor field-effect transistor (MOSFET) is arranged. An annular P well region is embedded between an edge of the semiconductor substrate and the cell region. The polysilicon diode is arranged in the annular P well region.

### SUMMARY

In the semiconductor device described in Patent Document 1, a P well region is formed in a lower layer of a polysilicon diode which is a temperature sensing diode. In this case, a source potential is provided to the P well region, making it possible to suppress an output of the temperature sensing diode from becoming unstable under the influence of a drain voltage or substrate voltage fluctuation. However, a process of forming an insulated gate type power transistor does not necessarily include a process of forming a P well region. If the process of forming an insulated gate type power transistor does not include the process of forming a P well region, an additional process of forming the P well region would be necessary just to stabilize the output of the temperature sensing diode.

Other problems and novel features will become apparent from the description of the present specification and the accompanying drawings.

According to an embodiment, there is provided a semiconductor device having a gate insulating type transistor, a temperature sensing diode, and a substructure of the temperature sensing diode. The substructure of the temperature sensing diode includes a source field plate arranged in periodically formed trenches, and a diffusion layer formed between adjacent trenches. The source field plate and the diffusion layer are connected to a source potential.

According to the embodiment, the semiconductor device having the gate insulating type transistor and the temperature sensing diode can stabilize a forward output voltage of the temperature sensing diode without adding a significant number of processes.

### BRIEF DESCRIPTION OF THE DRAWINGS

FIG. 1 is a cross-sectional view of an example of a structure of a semiconductor device according to a first embodiment of the present disclosure.

FIG. 2 is a top view of an example of a planar structure of the temperature sensing diode.

FIG. 3 is a cross-sectional view of the semiconductor device in a manufacturing process thereof.

FIG. 4 is a cross-sectional view of the semiconductor device in the manufacturing process thereof.

FIG. 5 is a cross-sectional view of the semiconductor device in the manufacturing process thereof.

FIG. 6 is a cross-sectional view of the semiconductor device in the manufacturing process thereof.

FIG. 7 is a cross-sectional view of the semiconductor device in the manufacturing process thereof.

FIG. 8 is a cross-sectional view of the semiconductor device in the manufacturing process thereof.

FIG. 9 is a cross-sectional view of the semiconductor device in the manufacturing process thereof.

FIG. 10 is a cross-sectional view of the semiconductor device in the manufacturing process thereof.

FIG. 11 is a cross-sectional view of the semiconductor device in the manufacturing process thereof.

FIG. 12 is a cross-sectional view of the semiconductor device in the manufacturing process thereof.

FIG. 13 is a cross-sectional view of the semiconductor device in the manufacturing process thereof.

FIG. 14 is a cross-sectional view of the semiconductor device in the manufacturing process thereof.

FIG. 15 is a cross-sectional view of the semiconductor device in the manufacturing process thereof.

FIG. 16 is a cross-sectional view of an example of a structure of the semiconductor device according to a second embodiment of the present disclosure.

FIG. 17 is a cross-sectional view of the semiconductor device in the manufacturing process thereof.

FIG. 18 is a cross-sectional view of an example of a structure of the semiconductor device according to a third embodiment of the present disclosure.

FIG. 19 is a top view of an example of a planar structure of the temperature sensing diode.

FIG. 20 is a cross-sectional view of the semiconductor device in the manufacturing process thereof.

FIG. 21 is a cross-sectional view of the semiconductor device in the manufacturing process thereof.

### DETAILED DESCRIPTION

Hereinafter, embodiments of the present invention in which the above-described means for solving the problem are applied will be described in detail with reference to the drawings. The following descriptions and attached drawings have been abbreviated and simplified as appropriate for clarity. In each of the drawings, identical elements are denoted by an identical reference sign, and redundant descriptions are omitted as appropriate.

In the embodiments described below, the invention will be described in a plurality of sections or embodiments if necessary for the sake of convenience. However, these sections or embodiments are not irrelevant to each other unless otherwise clearly specified, and one section or embodiment partially or entirely corresponds to another section or embodiment as a modification, detailed or supplementary description, or the like. In addition, in the embodiments described below, when referring to the number of a component (including number of pieces, numerical value, amount, and range), the number is not limited to a specified number and may be less than or greater than this number unless otherwise clearly specified or unless it is obvious from the context that the number is limited to the specified number in principle.

Further, in the embodiments described below, each component (including an operational step) is not indispensable unless otherwise clearly specified or unless it is obvious from the context that the component is indispensable in principle. Likewise, in the embodiments described below, when referring to a shape, a positional relation, or the like of a component or the like, a substantially approximate shape, a similar shape, or the like is included unless otherwise clearly specified or unless it is obvious from the context that the shape, the positional relation, or the like of the component differs in principle. The same applies to the above-described numerical value (including number of pieces, numerical value, amount, and range) and the like.

In the following embodiments, a MOSFET includes not only an FET in which a gate insulating film is an oxide film, but also an FET in which an insulating film other than an oxide film is used as the gate insulating film. In addition, the MOSFET includes not only an FET in which a gate electrode is formed by a metal, but also an FET in which a conductor other than a metal is used as the gate electrode. In the following embodiments, an example in which an insulated gate type transistor with a split gate structure is a MOSFET will be described. However, the insulated gate type transistor is not limited to a MOSFET, and may be an insulated gate bipolar transistor (IGBT).

### First Embodiment

FIG. 1 is a cross-sectional view of an example of a structure of a semiconductor device according to a first embodiment of the present disclosure. A semiconductor device 100 has a semiconductor substrate 101, a MOSFET is an insulated gate type transistor, and a temperature sensing diode 120. The semiconductor substrate 101 is an N type semiconductor substrate. In the present embodiment, the MOSFET 110 is a vertical MOSFET in which one surface of the semiconductor substrate 101 is a source and the other surface is a drain. The semiconductor device 100 is, for example, a 100 V class power discrete semiconductor.

In a region of the MOSFET 110, a plurality of trenches 111 are periodically formed in the semiconductor substrate 101. The MOSFET 110 has a source field plate 113 and a gate electrode 114 embedded in each of the trenches 111 via an insulating film 112. The source field plate 113 is provided with a source potential. The MOSFET 110 has a channel P diffusion layer 115 and a source N+ diffusion layer 116 between two adjacent gate electrodes 114. Each of the gate electrodes 114 and the source N+ diffusion layer 116 are covered by insulating films 135 and 136. The MOSFET 110 is a transistor having a split gate structure in which the gate electrode 114 and a source field plate 133 to which a source potential is provided are embedded in each of the trenches 111.

The temperature sensing diode 120 has a P type region 121 and an N type region 122. The temperature sensing diode 120 is formed of, for example, polysilicon. The P type region 121 and the N type region 122 are formed by, for example, introducing impurities into each polysilicon. The MOSFET 110 generates heat when a current flow occurs. The temperature sensing diode 120 is a diode for temperature measurement used to measure the temperature of the semiconductor device 100.

A plurality of trenches 131 are formed in the semiconductor substrate 101 in a region on a lower layer side of the temperature sensing diode 120. A width and depth of each of the trenches 131 are set to be equal to a width and depth of each of the trenches 111 in the MOSFET 110. A distance between two adjacent trenches 131, that is, pitch “a”, is equal to a pitch “b” between the trenches 111. The source field plate 133 is arranged in the trenches 131 via an insulating film 132. The insulating film 132 is also referred to as a field plate insulating film. A P type diffusion layer 134 is formed between two adjacent trenches 131. A position of a bottom portion of the P type diffusion layer 134 in a substrate depth direction is shallower than that of a bottom portion of the gate electrode 114 of the MOSFET 110. The source field plate 133 and the P type diffusion layer 134 are each provided with a source potential.

In the region on the lower layer side of the temperature sensing diode 120, an insulating film 135 is formed on an upper layer side of the source field plate 133 and of the P type diffusion layer 134. The insulating film 135 covers the source field plate 133 and the P type diffusion layer 134. The temperature sensing diode 120 is formed on an upper layer of the insulating film 135. The insulating film 135 is also referred to as a diode bottom insulating film. The insulating film 136 is formed on an upper layer side of the temperature sensing diode 120 and of the insulating film 135. The insulating films 135 and 136 are formed by using, for example, a silicon oxide film formed by chemical vapor deposition (CVD). The insulating films 135 and 136 each have a thickness of, for example, approximately 150 nm.

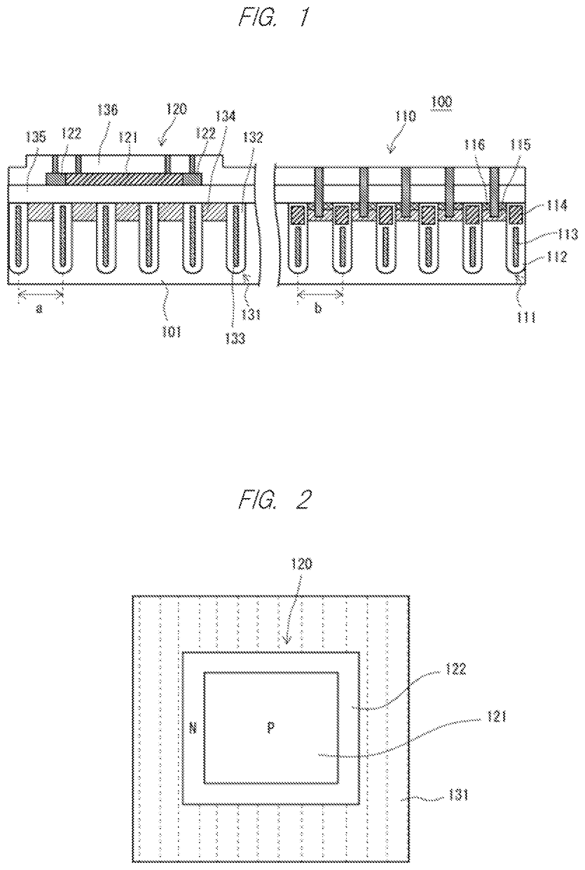

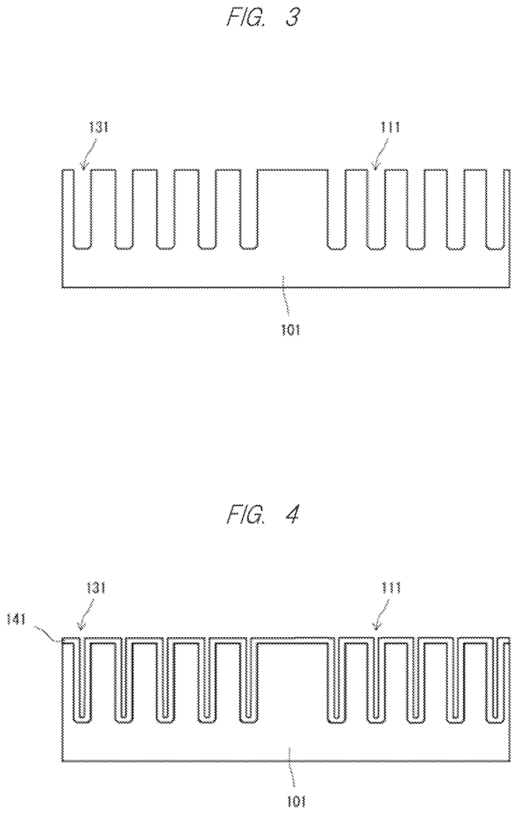

FIG. 2 is a top view of an example of the planar structure of the temperature sensing diode 120. As shown in FIG. 2, the P type region 121 in the temperature sensing diode 120 is formed in, for example, a rectangular shape. The N type region 122 is formed so as to surround the rectangular P type region 121. In the semiconductor substrate 101, the plurality of trenches 131 having a predetermined pitch therebetween and extending in a predetermined direction are formed in a lower portion of the temperature sensing diode 120. In addition, the plurality of P type diffusion layers 134 having a predetermined pitch therebetween and extending in a predetermined direction are formed in the lower portion of the temperature sensing diode 120. As shown in FIG. 1, the source field plate 133 is arranged in each of the trenches 131.

In the present embodiment, the semiconductor device 100 has the source field plate 133 and the P type diffusion layer 134 to which source potential is provided as the substructure of the temperature sensing diode 120. In the semiconductor device 100, the substructure of the temperature sensing diode 120 is set to be the source potential, so that it is possible to suppress an effect of a drain potential fluctuation of the MOSFET 110, that is, a substrate potential fluctuation, on the forward output voltage of the temperature sensing diode 120.

In addition, the substructure of the temperature sensing diode 120 in the present embodiment has a structure similar to that of the MOSFET 110 which is a main body cell. The trenches 131 in the lower portion of the temperature sensing diode 120 can be formed at the same time as the trenches 111 in the MOSFET 110. In addition, the source field plate 133 of the lower portion of the temperature sensing diode 120 can be formed at the same time as the source field plate 113 of the MOSFET 110. Further, the P type diffusion layer 134 of the lower portion of the temperature sensing diode 120 can be formed at the same time as the channel P diffusion layer 115 of the MOSFET 110.

Hereinafter, a manufacturing process of the semiconductor device 100 will be described. FIGS. 3 to 15 show cross sections of the semiconductor device 100 in manufacturing processes thereof. As shown in FIG. 3, in a process of forming trenches, the plurality of trenches 111 are formed in a region where the MOSFET of the N type semiconductor substrate 101 is formed. In addition, the plurality of trenches 131 are formed in a region of the semiconductor substrate 101 where the substructure of the temperature sensing diode is formed. Next, as shown in FIG. 4, in a process of forming a feed plate insulating film, an insulating film 141 is formed on the surface of the semiconductor substrate 101. The insulating film 141 corresponds to the insulating film 112 (see FIG. 1) of the MOSFET 110. In addition, the insulating film 141 corresponds to the insulating film 132 of the substructure of the temperature sensing diode.

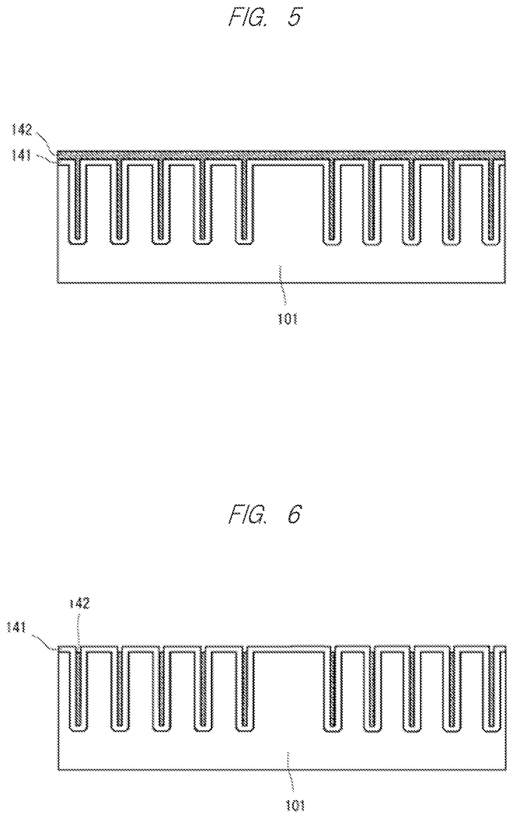

As shown in FIG. 5, in a process of forming electrodes, polysilicon 142 is deposited on the insulating film 141. The deposited polysilicon is planarized by chemical mechanical polishing (CMP). As shown in FIG. 6, in an etching process, the polysilicon 142 is entirely etched to remove the polysilicon 142 protruding from the trenches 111 and 131.

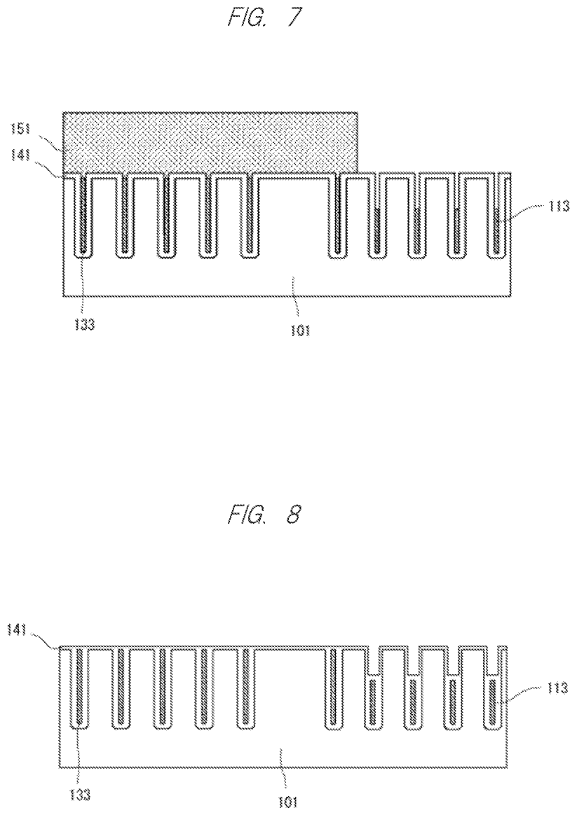

Then, as shown in FIG. 7, a region of the substructure of the temperature sensing diode is covered by a photoresist 151, and the polysilicon 142 is etched using the photoresist 151 as a mask to remove a portion of the polysilicon 142 in each of the trenches 111. The polysilicon 142 remaining in each of the trenches 111 corresponds to the source field plate 113 of the MOSFET 110. In addition, the polysilicon 142 in each of the trenches 131 corresponds to the source field plate 133 of the substructure of the temperature sensing diode.

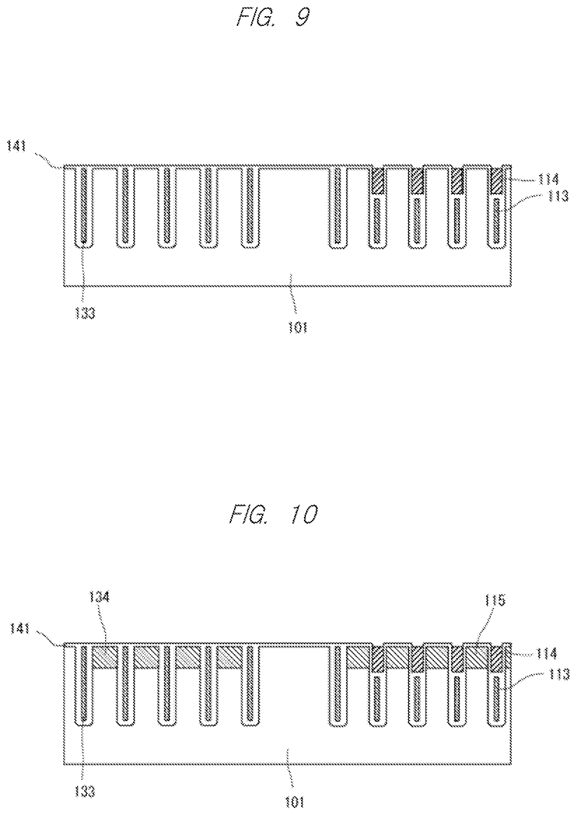

Next, as shown in FIG. 8, in a process of forming a gate oxide film, etching is performed to remove a portion of the insulating film 141. As shown in FIG. 9, in a process of forming a gate electrode, polysilicon is deposited in each of the trenches 111 to form the gate electrode 114. As shown in FIG. 10, in a process of forming a channel P diffusion layer, the channel P diffusion layer 115 is formed between two adjacent trenches 111. In addition, the P type diffusion layer 134 is formed between two adjacent trenches 131. As shown in FIG. 11, in a process of forming a source N+ diffusion layer, the source N+ diffusion layer 116 is formed on a portion of the channel P diffusion layer 115.

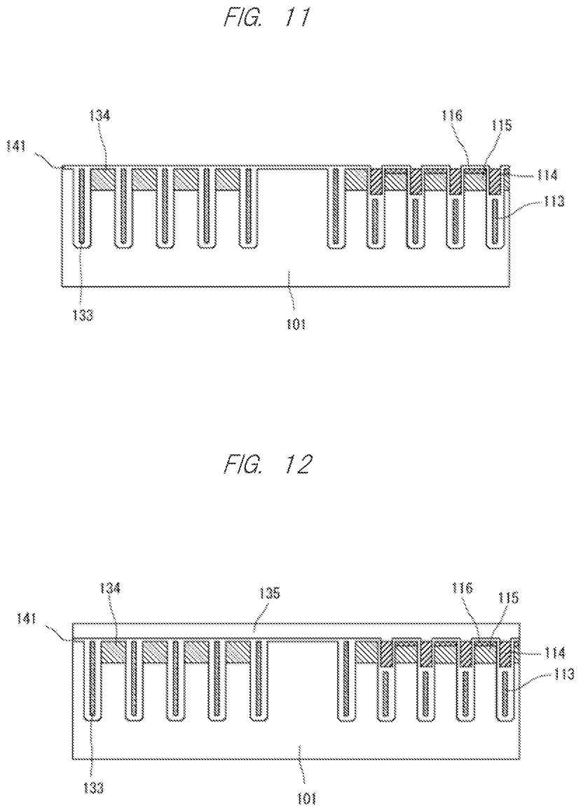

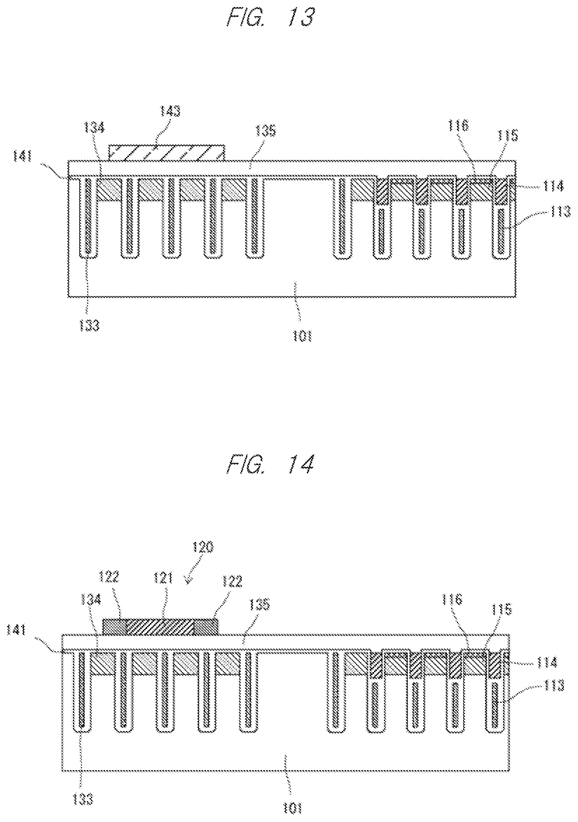

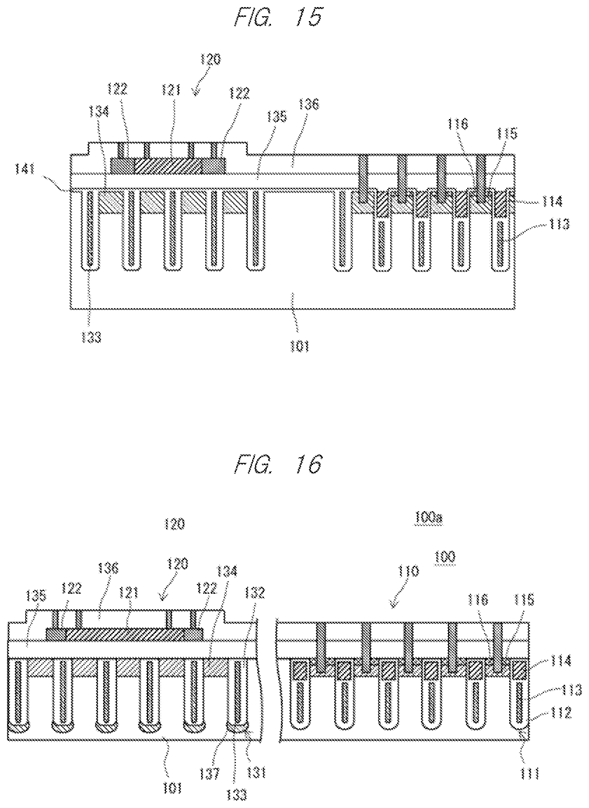

As shown in FIG. 12, in a process of forming a diode bottom insulating film, the surface of the semiconductor substrate 101 is covered by the insulating film 135. Then, as shown in FIG. 13, in a process of forming polysilicon, the polysilicon 143 is formed on a portion of the insulating film 135 where the temperature sensing diode 120 is formed. As shown in FIG. 14, in a process of forming a temperature sensing diode, impurities are introduced into the polysilicon 143 to form the P type region 121 and the N type region 122. Then, as shown in FIG. 15, the insulating film 136 is formed on the surface of the semiconductor substrate 101 so as to cover the temperature sensing diode 120.

### [Effects]

The semiconductor device 100 according to the present embodiment has a substructure of the temperature sensing diode 120 provided with trenches 131 in which the source field plate 133 is embedded and the P type diffusion layer 134. The source field plate 133 and the P type diffusion layer 134 are each connected to the source potential. This configuration allows the substructure of the temperature sensing diode 120 to be fixed at the source potential even if the substrate potential, that is, the drain potential of the MOSFET 110, fluctuates. As a result, even if the substrate potential fluctuates, the output of the temperature sensing diode 120 can be suppressed from becoming unstable. In addition, in the present embodiment, the source field plate 133 embedded in each of the trenches 131 functions as a built-in RC snubber. Thus, a recovery surge reduction effect can be expected in the semiconductor device 100.

In comparison with Patent Document 1, a process of forming a P well would be necessary in Patent Document 1 since the P well is formed at the lower portion of the temperature sensing diode. However, the manufacturing process of the MOSFET 110 which is the main body cell does not include the process for forming a P well. Thus, if the P wells is to be formed at the lower portion of the temperature sensing diode, processes of photolithography, ion implantation, and high-temperature diffusion need to be added to the manufacturing process of the MOSFET 110. This increases the process cost.

In the present embodiment, the substructure of the temperature sensing diode 120 has a structure similar to that of the MOSFET 110. Thus, the trenches 131, the source field plate 133, and the P type diffusion layer 134 of the substructure of the temperature sensing diode 120 can be formed simultaneously with the trenches 111, the source field plate 133, and the channel P diffusion layer 115 of the MOSFET 110, respectively. Therefore, the present embodiment can suppress the effect of substrate fluctuation on the forward output voltage of the potential temperature sensing diode 120 without increasing the process cost.

Note that, in the semiconductor device 100, the pitch “a” between the trenches 131 in the substructure of the temperature sensing diode may be larger than the pitch “b” between the trenches 111 in the MOSFET 110. By providing a larger pitch “a” between the trenches 131 in the substructure of the temperature sensing diode, breakdown voltage of the substructure of the temperature sensing diode can be made to be higher than that of the main body cell. However, if the pitch “a” between the trenches 131 is made to be significantly larger, breakdown voltage will decrease. In order to prevent a significant decrease in the breakdown voltage, particularly in a low-temperature environment, the pitch “a” between the trenches 131 is set to be, for example, larger than the pitch “b” between the trenches 111 but less than 1.1 times the pitch “b” between the trenches 111.

When the pitch “a” between the trenches 131 is set to be larger than the pitch “b” between the trenches 111 and less than or equal to 1.1 times the pitch “b”, the breakdown voltage of the substructure of the temperature sensing diode 120 can be set to be higher than that of the main body cell where the MOSFET 110 is formed. In this case, even if a voltage of BVDSS or higher is applied between the drain and the source of the MOSFET 110 and avalanche breakdown occurs, no current flows to the P type diffusion layer 134 of the substructure of the temperature sensing diode 120, and the potential fluctuation of the substructure of the temperature sensing diode 120 can be suppressed. Thus, the output stability of the temperature sensing diode can be improved.

### Second Embodiment

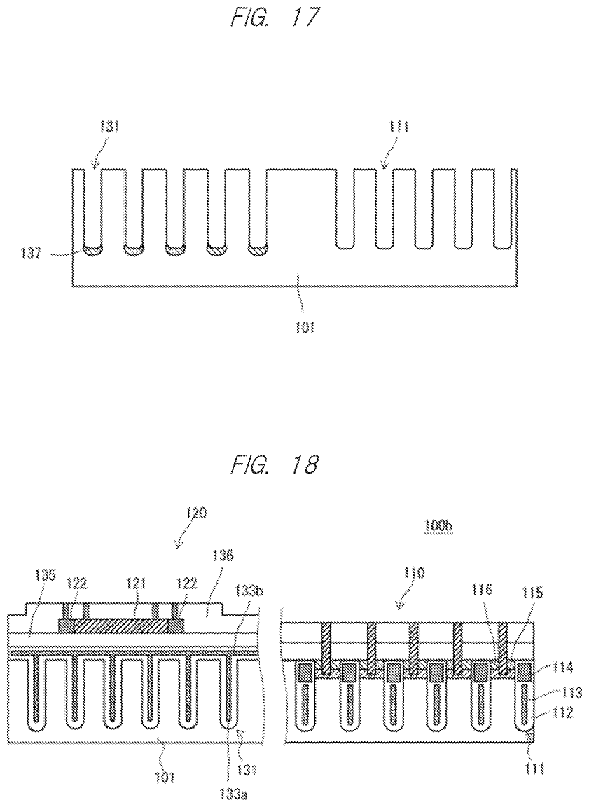

FIG. 16 is a cross-sectional view of an example of a structure of the semiconductor device according to a second embodiment of the present disclosure. The configuration of the semiconductor device 100a shown in FIG. 16 differs from that of the semiconductor device 100 shown in FIG. 1 in that boron 137 is injected into a bottom portion of each of the trenches 131 in the substructure of the temperature sensing diode. In the present embodiment, the pitch between the trenches 131 in the substructure of the temperature sensing diode may be equal to or larger than the pitch between the trenches 111 in the MOSFET 110.

FIG. 17 is a cross-sectional view of the semiconductor device 100a in the manufacturing process thereof. In the process shown in FIG. 3, the plurality of trenches 111 are formed in the semiconductor substrate 101. Then, as shown in FIG. 17, in a process of injecting boron, the boron 137 is injected into a bottom portion of each of the trenches 111. Subsequent processes may be similar to those shown in FIGS. 4 to 15.

### [Effects]

In the present embodiment, the substructure of the temperature sensing diode 120 has the boron 137 injected into the bottom portion of each of the trenches 131. Injecting the boron 137 into the bottom portion of each of the trenches 131 in which the source field plate 133 is embedded allows the breakdown voltage of the substructure of the temperature sensing diode 120 to be higher than when boron is not injected. This configuration allows the breakdown voltage of the substructure of the temperature sensing diode 120 in the semiconductor device 100 to be higher than that of the MOSFET 110. In this case, even if a voltage of BVDSS or higher is applied between the drain and the source of the MOSFET 110 and avalanche breakdown occurs, the potential fluctuation of the substructure of the temperature sensing diode 120 can be suppressed. Thus, the output stability of the temperature sensing diode can be improved. Other effects are similar to those described for the first embodiment.

### Third Embodiment

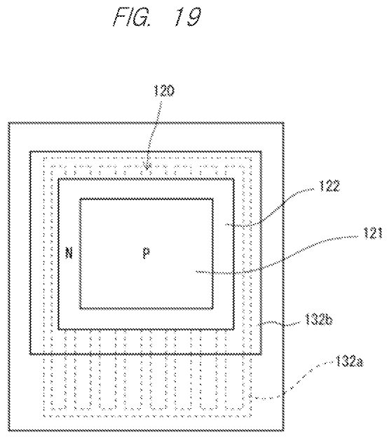

FIG. 18 is a cross-sectional view of an example of a structure of the semiconductor device according to a third embodiment of the present disclosure. FIG. 19 is a top view of an example of a planar structure of the temperature sensing diode. In the present embodiment, the source field plate arranged on the substructure of the temperature sensing diode 120 has a source field plate 133a embedded in each of the trenches 131, and a flat source field plate 133b. The source field plate 133b is also referred to as a diode bottom plate. The source field plate 133a is also referred to as a first portion of the source field plate. The source field plate 133b is also referred to as a second portion of the source field plate.

In the present embodiment, the source field plate 133b covers the entire lower portion of the temperature sensing diode 120 via the insulating film 135. The source field plates 133a and 133b are each provided with a source potential. The semiconductor device 100b according to the present embodiment differs from the semiconductor device 100 according to the first embodiment shown in FIG. 1 in that no P type diffusion layer 134 is formed between two adjacent trenches 131. The semiconductor device 100b may be configured in the same manner as the semiconductor device 100a shown in FIG. 16, with the boron 137 injected into the bottom portion of each of the trenches 131. In the present embodiment, the source field plate 133a embedded in each of the trenches 131, and the source field plate 133b which is the diode bottom plate also function as the built-in RC snubber.

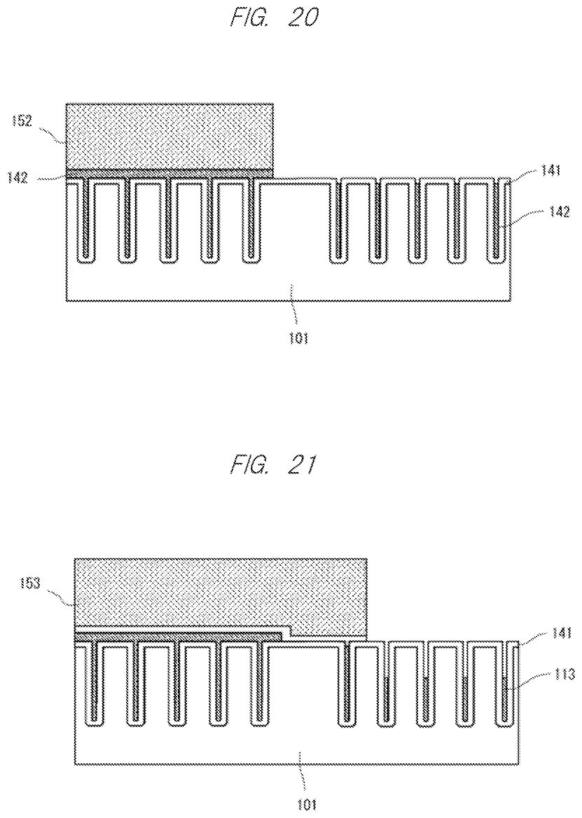

FIGS. 20 and 21 are cross-sectional views of the semiconductor device 100b in the manufacturing processes thereof. In the processes shown in FIGS. 3 to 5, the plurality of trenches 111 are formed in the semiconductor substrate 101, the insulating film 141 is formed on the surface of the semiconductor substrate 101, and the polysilicon 142 is deposited on the insulating film 141. Then, as shown in FIG. 20, in a process of forming a diode bottom plate, a region of the substructure of the temperature sensing diode is covered by a photoresist 152, and the polysilicon 142 is etched using the photoresist 152 as a mask. This process removes the polysilicon 142 protruding from the trenches 111 in the region of the MOSFET 110. As shown in FIG. 20, in the region corresponding to the substructure of the temperature sensing diode 120, the polysilicon 142 on the surface of the semiconductor substrate 101 is not removed.

Next, as shown in FIG. 21, a region of the substructure of the temperature sensing diode is covered by the photoresist 153, and the polysilicon 142 is etched using the photoresist 153 as a mask to remove a portion of the polysilicon 142 in each of the trenches 111. The polysilicon 142 in each of the trenches 111 corresponds to the source field plate 113. Subsequent processes may be similar to those shown in FIGS. 8 to 15, except that the P type diffusion layer 134 is not formed in the region of the substructure of the temperature sensing diode, unlike the process shown in FIG. 10.

In the present embodiment, the substructure of the temperature sensing diode 120 has the source field plate 133b covering the entire temperature sensing diode 120. In this case, the breakdown voltage of the substructure of the temperature sensing diode 120 can be set to be higher than that of the configuration of the first embodiment shown in FIG. 1. In the present embodiment, the semiconductor device 100b allows the breakdown voltage of the substructure of the temperature sensing diode 120 to be higher than that of the MOSFET 110. In this case, even if a voltage of BVDSS or higher is applied between the drain and the source of the MOSFET 110 and avalanche breakdown occurs, the potential fluctuation of the substructure of the temperature sensing diode 120 can be suppressed.

In the present embodiment, photolithography is added to the manufacturing process of the MOSFET 110 to form the diode bottom plate. However, the addition of photolithography is simpler than the process of forming a P well. Thus, the present embodiment does not require adding a significant number of processes in forming the substructure of the temperature sensing diode. Therefore, the present embodiment can stabilize the forward output voltage of the temperature sensing diode 120 even if the substrate potential fluctuates, without increasing the process cost.

Note that the semiconductor device according to the above-described embodiments may have a configuration in which conductivity types (P type or N type) of a semiconductor substrate, semiconductor layer, diffusion layer or the like are inverted. For example, one of the N type and P type conductivity type can be a first conductivity type and the other conductivity type can be a second conductivity type. In such a case, the first conductivity type can be the P type, and the second conductivity type can be the N type, or conversely, the first conductivity type can be the N type and the second conductivity type can be the P type.

In the foregoing, the invention made by the present inventors has been described in detail based on the embodiments. However, the present invention is not limited to the above-described embodiments, and various modifications can be made without departing from the gist of the invention.

What is claimed is:

1. A semiconductor device comprising:
a semiconductor substrate of a first conductivity type;
a gate insulating type transistor formed on the semiconductor substrate and having a split gate structure;
a diode for temperature measurement; and
a substructure of the diode formed on the semiconductor substrate,
wherein the substructure of the diode has:
trenches periodically formed in the semiconductor substrate;
a source field plate arranged in each of the trenches via an insulating film, the source field plate being provided with a source potential;
a diffusion layer of a second conductivity type opposite the first conductivity type formed between adjacent trenches and to which the source potential is provided; and
a diode bottom insulating film covering the source field plate and the diffusion layer and having an upper portion on which the diode is formed.

2. The semiconductor device according to claim 1,
wherein the transistor has:
trenches periodically formed in the semiconductor substrate;
a source field plate and a gate electrode arranged in each of the trenches via an insulating film; and
a diffusion layer of the first conductivity type and the diffusion layer of the second conductivity type formed between adjacent trenches and stacked in a depth direction of the semiconductor substrate.

3. The semiconductor device according to claim 2,
wherein each of the trenches in the substructure of the diode is formed in the semiconductor substrate in a process of forming the trenches in the transistor,
wherein the source field plate of the substructure of the diode is formed in a process of forming the source field plate of the transistor, and
wherein the diffusion layer of the second conductivity type of the substructure of the diode is formed in a process of forming the diffusion layer of the second conductivity type of the transistor.

4. The semiconductor device according to claim 2,
wherein a pitch between the trenches in the substructure of the diode is larger than a pitch between the trenches in the transistor.

5. The semiconductor device according to claim 1, further having boron injected into a bottom portion of each of the trenches in the substructure of the diode.

6. A semiconductor device comprising:
a semiconductor substrate of a first conductivity type;
a gate insulating type transistor formed on the semiconductor substrate and having a split gate structure;
a diode for temperature measurement; and
a substructure of the diode formed on the semiconductor substrate,
wherein the substructure of the diode has:
trenches periodically formed in the semiconductor substrate;
a source field plate provided with a source potential, and having a first portion arranged in each of the trenches via an insulating film, and a flat second portion arranged on a surface of the semiconductor substrate via an insulating film; and
a diode bottom insulating film covering the surface of the semiconductor substrate and the source field plate, and having an upper portion on which the diode is formed.

7. The semiconductor device according to claim 6,
wherein the transistor has:
trenches periodically formed in the semiconductor substrate;
a source field plate and a gate electrode arranged in each of the trenches via an insulating film; and
a diffusion layer of the first conductivity type and the diffusion layer of the second conductivity type formed between adjacent trenches and stacked in a depth direction of the semiconductor substrate.

8. The semiconductor device according to claim 7,
wherein each of the trenches in the substructure of the diode is formed in the semiconductor substrate in a process of forming trenches in the transistor, and
wherein the source field plate of the substructure of the diode is formed in a process of forming the source field plate of the transistor.

9. The semiconductor device according to claim 6, further having boron injected into a bottom portion of each of the trenches in the substructure of the diode.
